(19) United States
(12) Patent Application Publication
(10) Pub. No.: US 2019/0195693 A1
(43) Pub. Date: Jun. 27, 2019

(54) PYROELECTRIC SENSOR WITH IMPROVED ELECTROMAGNETIC SHIELDING

(71) Applicant: COMMISSARIAT A L'ENERGIE ATOMIQUE ET AUX ENERGIES ALTERNATIVES, Paris (FR)

(72) Inventors: Mohammed BENWADIH, Champigny Sur Marne (FR); Jean-Francois MAINGUET, Grenoble (FR); Amelie REVAUX, Voiron (FR); Laurent TOURNON, Saint-Egreve (FR)

(73) Assignee: COMMISSARIAT A L'ENERGIE ATOMIQUE ET AUX ENERGIES ALTERNATIVES, Paris (FR)

(21) Appl. No.: 16/230,162

(22) Filed: Dec. 21, 2018

(30) Foreign Application Priority Data
Dec. 22, 2017 (FR) 17 62925

(51) Int. Cl. G01J 5/06; G01J 5/20; G01J 5/34; H01L 27/16; H01L 37/02; H01L 23/552

(52) U.S. Cl. CPC G01J 5/06; G01J 5/20; G01J 5/34; G06K 9/00006; H01L 37/02; H01L 23/552; G01J 2005/065; H01L 27/16

(57) ABSTRACT

The invention relates to a heat pattern sensor comprising a matrix of pyroelectric capacitances. The heat pattern sensor further comprises an electromagnetic shielding stage, electrically conducting, situated between a stage including a pyroelectric material and a protective layer of the matrix of pixels. The electromagnetic shielding stage includes an insulating layer, and a plurality of pads distributed in the insulating layer, the pads having a thermal conductivity greater than that of the insulating layer. The invention makes it possible to obtain at one and the same time rapid heat transfers through the electromagnetic shielding stage, and low lateral heat transfers, from one pixel to the other of the sensor.

### TECHNICAL FIELD

The invention relates to a heat pattern sensor of pyroelectric sensor type.

Such a sensor forms for example a papillary print sensor, notably a finger print sensor.

### PRIOR ART

A pyroelectric sensor exploits the pyroelectric properties of a material, that is to say its capacity to generate electrical charges in response to a variation in temperature.

Such a sensor comprises a matrix of pyroelectric capacitances, each forming a transducer to translate a temporal variation in temperature into an electrical signal.

Each pyroelectric capacitance comprises a pyroelectric material portion, arranged between a lower electrode and an upper electrode. One of the electrodes is placed at a constant potential, and forms a reference electrode. The other electrode, designated charge collection electrode, collects the pyroelectric charges generated by the pyroelectric material in response to a variation in temperature. The charge collection electrode is connected to a reading circuit, for measuring the quantity of collected charges.

In operation, an object is pressed against a contact surface of the sensor.

The detection may simply exploit a temperature difference between this object and said contact surface. The sensor then carries out a passive type detection.

In the case of a finger print detection, the finger is pressed against the contact surface of the sensor.

At the level of the ridges of the print, the finger is in direct physical contact with the sensor. A thermal transfer between the skin and the contact surface of the sensor takes place by conduction, which leads to a first temporal variation in temperature.

At the level of the valleys of the print, the finger is not in direct physical contact with the sensor. A thermal transfer between the skin and the contact surface of the sensor takes place through air. Air has heat insulating properties, which leads to a second temporal variation in temperature, less important.

The difference between these two temporal variations in temperature is reflected by a difference between the signals measured by the pyroelectric capacitances, depending on whether they lie under a valley or under a ridge of the print. The image of the print then has a contrast that depends on this difference.

After several seconds, the temperature of the finger and the temperature of the contact surface are homogenised, and it is no longer possible to obtain a satisfactory contrast.

To overcome this drawback, heating means are added under the contact surface, in order to dissipate a certain quantity of heat in each pixel of the sensor. The variation in temperature measured in each pixel of the sensor then relates to the measure to which this quantity of heat is evacuated from the pixel. This makes it possible to improve, and to conserve over time, the contrast of an image acquired by means of said sensor. The sensor then carries out an active type detection. Such a sensor is described for example in the patent application EP 2 385 486.

In the case of finger print detection, the variation in temperature is important at the level of the valleys of the print, where heat is transferred to the finger only through air, and lower at the level of the ridges of the print, where heat is transferred efficiently to the finger, by conduction.

Whatever the type of detection implemented, a pyroelectric sensor advantageously comprises a so-called electromagnetic shielding stage, that is to say an electrically conducting stage, able to be connected to a constant potential source, and forming an electromagnetic shielding between an object to image applied against the contact surface of the sensor, and the pyroelectric material portions of the pixels of the sensor. The electromagnetic shielding stage offers protection with regard to electrostatic parasites, notably around 50 Hz, avoiding the recovery of electromagnetic noise in the measurements made. It also makes it possible to protect the sensor with regard to electrostatic discharges, brought by contact of the object to image lying against the contact surface of the sensor. In the case of a papillary print sensor, it offers protection with regard to electrostatic discharges, brought by contact with the skin when the finger touches the contact surface of the sensor.

The French patent application n° 16 57391, filed on the 29 Jul. 2016, describes an example of a pyroelectric sensor able to carry out an active type detection, and comprising such an electromagnetic shielding stage. The electromagnetic shielding stage is constituted of a single layer made of electrically conducting material.

The electromagnetic shielding stage extends between the contact surface of the sensor, and the pyroelectric material portions of the pixels of the sensor, preferably under a protective layer of the sensor.

In order not to hinder heat exchanges between an object to image, pressed against said contact surface, and the pyroelectric material portions, the electromagnetic shielding stage must be able to transmit heat.

However, if this stage is constituted of a layer of a material having a too high thermal conductivity, there is a risk that heat propagates laterally in the electromagnetic shielding stage, from one pixel to the other of the sensor. This phenomenon, designated diathermy, or crosstalk, prevents a thermal pattern on the contact surface being reproduced faithfully at the level of the pyroelectric material portions.

Conversely, if this stage is constituted of a layer of a material having a too low thermal conductivity, exchanges of heat through this stage are slowed down, also slowing down the reading of the pixels of the sensor. This slower reading may pose difficulties, in particular for sensors of large dimensions.

One objective of the present invention is to propose a solution so that the electromagnetic shielding stage of a pyroelectric sensor offers a great speed of heat transfer, while limiting heat transfers from one pixel to the other of the sensor.

### DESCRIPTION OF THE INVENTION

This objective is attained with a heat pattern sensor comprising a matrix of pixels, each pixel comprising at least one pyroelectric capacitance, formed by a pyroelectric material portion arranged between a so-called charge collection electrode and a so-called reference electrode, and the matrix of pixels comprising, superimposed above a substrate:
a stage of charge collection electrodes, comprising the charge collection electrodes of each of the pixels;
a stage including a pyroelectric material, comprising the pyroelectric material portions of each of the pixels; and
a protective layer, forming an outer layer of the matrix of pixels.

The matrix of pixels further comprises a so-called electromagnetic shielding stage, electrically conducting, situated between the stage including a pyroelectric material and the protective layer.

According to the invention, the electromagnetic shielding stage includes a layer, called insulating layer, and a plurality of pads distributed in the insulating layer. Each pad extends over more than half of the thickness of the insulating layer and has a diameter less than a pixel pitch of the matrix of pixels. The pads have a thermal conductivity greater than that of the insulating layer.

In other words, the pads have a high thermal conductivity, and extend into an insulating layer having a low thermal conductivity.

Thanks to their high thermal conductivity, heat propagates rapidly in the pads, in particular along an axis orthogonal to the plane of the substrate.

Heat also propagates laterally in each pad, in planes parallel to the plane of the substrate. However, each pad extends into the insulating layer, of low thermal conductivity, which limits the diffusion of heat from one pad to the other of the electromagnetic shielding stage, and thus from one pixel to the other of the matrix of pixels.

The electromagnetic shielding stage according to the invention thus offers at one and the same time:
rapid thermal transfers, along an axis orthogonal to the plane of the substrate; and
low lateral diffusion of heat, from one pixel to the other of the sensor.

Preferably, each pad extends into a single pixel of the matrix of pixels, without overstepping, even at the margin, onto a neighbouring pixel.

If need be, the electromagnetic shielding stage according to the invention may further form the reference electrodes of the pixels of the matrix of pixels. In an alternative, the reference electrodes extend into a stage of the sensor distinct from the electromagnetic shielding stage.

The pads may include metal or graphene, and the insulating layer may include at least one electrically conducting polymer. The pads may even be constituted of metal or graphene.

The invention also relates to a method for manufacturing the matrix of pixels of a heat pattern sensor according to the invention, in which a step of producing the electromagnetic shielding stage includes the following steps:
depositing the insulating layer, such that it extends without opening above the substrate;
depositing, on said insulating layer, an ink including particles in suspension in a solvent, the solvent being able to dissolve locally the insulating layer; and
evacuating the solvent, to form the pads of the electromagnetic shielding stage, distributed in the insulating layer.

### BRIEF DESCRIPTION OF THE DRAWINGS

The present invention will be better understood on reading the description of exemplary embodiments given for purely indicative purposes and in no way limiting, and by referring to the appended drawings in which:

FIGS. 1A and 1B schematically illustrate a first embodiment of a heat pattern sensor according to the invention;

FIG. 1C illustrates an alternative of the embodiment of FIGS. 1A and 1B;

FIGS. 2A and 2B schematically illustrate a second embodiment of a heat pattern sensor according to the invention;

FIG. 2C illustrates an alternative of the embodiment of FIGS. 2A and 2B; and

FIGS. 3A to 3C schematically illustrate a method according to the invention.

### DETAILED DESCRIPTION OF PARTICULAR EMBODIMENTS

For greater clarity, the axes (Ox), (Oy) and/or (Oz) of an orthonormal coordinate system have been represented in the figures. Scales are not respected in the figures, in particular the thicknesses of each of the layers and/or stages.

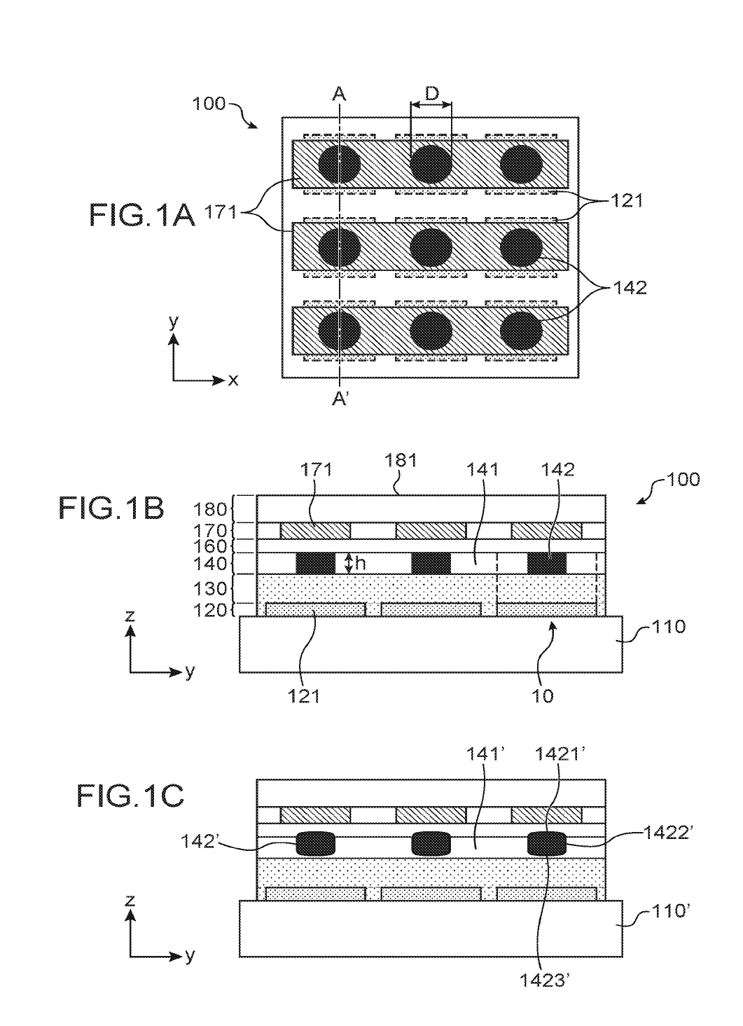

FIGS. 1A and 1B schematically illustrate a first embodiment of a heat pattern sensor 100 according to the invention. FIG. 1A is a schematic top view, in a plane parallel to the plane (xOy). FIG. 1B is a sectional view in a plane AA′ parallel to the plane (yOz).

The heat pattern sensor 100 comprises, superimposed above a substrate 110, along the axis (Oz) orthogonal to an upper or lower face of said substrate:
a stage 120 designated a charge collection electrode stage;
a stage 130 including a pyroelectric material;
an electromagnetic shielding stage 140;
an electrical insulation layer 160;
a heating stage 170; and
a protective layer 180.

This stack forms a matrix of pixels, in which each pixel comprises at least one pyroelectric capacitance, formed by a pyroelectric material portion arranged between a charge collection electrode, and a reference electrode. In this embodiment, the electromagnetic shielding stage 140 also forms a reference electrode common to all the pixels of the matrix of pixels.

The substrate 110 is for example made of glass, silicon, a plastic such as poly(ethylene terephthalate) (PET), poly(ethylene naphthalate) (PEN), polyimide (Kapton film), etc. It is preferably a flexible substrate, for example a substrate made of polyimide of 5 μm to 10 μm thickness, or made of a plastic such as PET.

It has an upper face and a lower face parallel with each other, and parallel to the plane (xOy). Hereafter, the plane of the substrate designates a plane parallel to these upper and lower faces.

The charge collection electrode stage 120 here comprises a matrix of charge collection electrodes 121, arranged in lines and in columns along the axes (Ox) and (Oy).

The charge collection electrodes are constituted of a metal such as gold or silver, or any other electrically conducting material.

They are distributed along the axes (Ox) and (Oy), according to a distribution pitch less than or equal to 150 μm. The distribution pitch is for example around 80 μm (i.e. a resolution of 320 dpi), or 90 μm. In an alternative, the distribution pitch may be 50.8 μm (i.e. a resolution of 500 dpi).

Each of the charge collection electrodes 121 here delimits, laterally, the pyroelectric capacitance 10 of one of the pixels of the matrix of pixels (see FIG. 1B).

The stage 130 including a pyroelectric material is here constituted of a solid layer including poly(vinylidene fluoride) (PVDF) or one of the derivatives thereof (notably the copolymer PVDF-TrFE, TrFE for tri-fluoro-ethylene).

In an alternative, the layer 130 includes aluminium nitride (AlN), barium titanate (BaTiO₃), lead zirconate titanate (PZT), or any other pyroelectric material.

The layer 130 extends in one piece, and without opening, covering all of the charge collection electrodes 121 of the stage 120.

Each portion of the layer 130, situated facing a charge collection electrode 121, forms the pyroelectric material portion of a pixel of the matrix of pixels.

The electromagnetic shielding stage 140 forms an electrically conducting stage, here having a heterogeneous structure, described hereafter.

It is able to be connected to a constant potential source, for example to the ground. The stage 140 preferably extends in one piece, and without opening, above all the charge collection electrodes 121 of the stage 120, that is to say passing through all the pixels of the matrix of pixels.

Here, the stage 140 also forms a reference electrode, common to all the pixels of the matrix of pixels. In other words, each portion of the stage 140, situated facing a charge collection electrode 121, forms the reference electrode of a pixel of the matrix of pixels.

The electrical insulation layer 160 is constituted of a dielectric material, for example polyimide. It preferably has a thickness less than 5 μm, for example equal to 1 μm.

According to the embodiment of FIGS. 1A and 1B, each pixel of the matrix of pixels further comprises a heating element, the heating elements here extending into the heating stage 170.

Here, the heating elements of a same line of pixels are electrically connected together to form a heating strip 171. The heating strips 171 are able to receive a heating current, to provide heating by Joule effect, so as to carry out an active type detection. They are preferably constituted of a metal, for example gold or silver.

The protective layer 180 forms the outermost layer of the sensor. It makes it possible to limit wear linked to repeated contacts with an object to image, notably with skin. The protective layer 180 is for example a layer made of DLC (Diamond Like Carbon), resin, polyimide, etc. It generally has a thickness comprised between several micrometres and 25 μm.

An upper face 181 of the protective layer 180, on the side opposite to the substrate 110, forms a contact surface of the thermal pattern sensor 100. In operation, an object to image such as a papillary print is applied against said contact surface 181, so as to produce thermal exchanges with the stage including a pyroelectric material.

According to the invention, the electromagnetic shielding stage 140 is constituted by:
an insulating layer, 141, made of electrically conducting material and poor heat conductor; and
a matrix of pads 142, made of electrically conducting material and good heat conductor.

The insulating layer 141 advantageously has a thickness less than or equal to 1.5 μm, preferably less than or equal to 1.0 μm. This thickness is equal for example to 600 nm.

The insulating layer 141 is preferably constituted of a material having a thermal conductivity less than or equal to 10 W·m⁻¹K⁻¹.

In an even more preferred manner, it is constituted of a material having a thermal conductivity less than or equal to 1 W·m⁻¹K⁻¹.

It is, for example, made of PEDOT:PSS (mixture of poly(3,4-ethylenedioxythiophene) (PEDOT) and sodium poly(styrene sulfonate) (PSS)), having a thermal conductivity of 0.3 W·m⁻¹K⁻¹. In an alternative, it is made of PEDOT.

PEDOT and PEDOT:PSS have the advantage that they may be deposited without necessity of a controlled atmosphere. Even so, other materials are not excluded, such as poly(p-phenylene sulphide), polypyrrole (PPY), polythiophene (PT), polyacetylene (PAC), polyaniline (PAni), melanin.

The insulating layer 141 is electrically conducting. Even so, it may have an electrical resistivity greater than that of a metal, since the insulating layer 141 is intended to withstand weak currents only. The insulating layer 141 has for example an electrical resistivity comprised between 10⁻⁸ am and 10⁻⁵ am (at 20° C.), for example 5.10⁻⁵ am for PEDOT.

The pads 142 are constituted of a material having a thermal conductivity greater than or equal to 50 W·m⁻¹K⁻¹.

In an even more preferred manner, they are constituted of a material having a thermal conductivity greater than or equal to 100 W·m⁻¹K⁻¹.

The thermal conductivity of the pads 142 is preferably at least ten times greater than that of the insulating layer 141.

The pads 142 include for example a metal such as silver, gold, copper, aluminium, etc. They are for example produced by means of an ink based on a metal, in particular an ink based on silver. When the pads are produced by means of an ink based on a metal, they are constituted of particles of metal placed one next to the other, with a more or less high percentage of volume occupation by the metal. The pads then have a thermal conductivity less than that of the pure metal. In its pure form, silver has a thermal conductivity of 429 W·m⁻¹K⁻¹. Pads produced by means of an ink based on silver have a thermal conductivity less than 429 W·m⁻¹K⁻¹ and greater than or equal to 69 W·m⁻¹K⁻¹, or even greater than or equal to 100 W·m⁻¹K⁻¹.

In an alternative, the pads 142 may include graphene (two-dimensional material of which the stack constitutes graphite, graphite being a crystalline form of carbon). They may be entirely constituted of graphene.

The pads 142 are electrically conducting, with an electrical resistivity comprised between 10⁻⁸ Ω·m and 10⁻⁵ am (at 20° C.). For the same reasons as mentioned above, pads produced by means of an ink based on a metal have an electrical resistivity greater than that of the pure metal. For example, silver in its pure form has an electrical resistivity of 1.57*10^{˜8} Ω·m (at 20° C.), whereas pads produced by means of an ink based on silver have an electrical resistivity comprised between 3*10⁻⁷ Ω·m and 6*10⁻⁶ Ω·m, at 20° C.

Here, the pads 142 are regularly distributed, in lines and in columns, such that each pixel of the matrix of pixel comprises a single and unique pad 142.

Preferably, the geometric centre of a pad 142 and the geometric centre of the associated pixel together define an axis parallel to the axis (Oz).

The pads 142 have for example a cylinder of revolution shape, having:
a diameter D (dimension in a plane parallel to the plane of the substrate 110); and
a height h (dimension along the axis (Oz), orthogonal to the plane of the substrate 110).

Here, each pad 142 extends along the axis (Oz) orthogonal to the plane of the substrate, over the whole thickness of the insulating layer 141.

Each pad 142 here has a height h equal to the thickness of the insulating layer.

This thickness is here less than 1 μm, for example equal to 0.5 μm.

The diameter D is less than the pixel pitch of the matrix of pixels, such that two neighbouring pads 142 are physically isolated from each other, by a part of the insulating layer 142.

This diameter D is comprised for example between 10 μm and 100 μm, preferably between 50 μm and 60 μm.

Since each pad 142 has a high thermal conductivity, heat circulates rapidly in the pad, along all the dimensions of space.

Along the axis (Oz), heat thus circulates rapidly through the electromagnetic shielding stage 140, while passing through the pads 142.

On the other hand, in planes parallel to the plane of the substrate, heat passes with difficulty from one pad 142 to the neighbouring pad, and thus from one pixel to the neighbouring pixel, thanks to the low thermal conductivity of the insulating layer extending between the pads.

The heterogeneous structure of the electromagnetic shielding stage 140 thereby makes it possible to obtain at one and the same time:
rapid thermal transfers, along an axis (Oz) orthogonal to the plane of the substrate; and
low lateral diffusion of heat, from one pixel to the other of the sensor.

FIG. 1C illustrates, in a sectional view in a plane parallel to the plane (yOz), an alternative of the embodiment of FIGS. 1A and 1B.

This alternative only differs from that of FIGS. 1A and 1B in that the pads 142′ do not extend over the whole thickness of the insulating layer 141′, and do not quite have a cylinder of revolution shape.

According to this alternative, each pad 142′ comprises:
an upper region 1421′, rounded, protruding above the upper face of the insulating layer 141′, on the side opposite to the substrate 110′;
a central body 1422′, of cylinder of revolution shape; and
a lower region 1423′, rounded, protruding in the direction of the substrate from a lower face of the central body 1422′, on the side of the substrate 110′.

The upper 1421′ and lower 1423′ regions do not overstep laterally, relative to the central body 1422′. Moreover, the upper regions 1421′ only slightly overstep above the upper face of the insulating layer 141′, for example by less than 500 nm along the axis (Oz) orthogonal to said face.

Whatever the case, the pads 142′ are physically isolated from each other, without direct physical contact between them.

The diameter of a pad 142′ here corresponds to the diameter of its cylindrical central body 1422′.

If need be, it is possible to define the diameter of a pad as being the greatest length measured along a rectilinear axis, on this pad, in a plane parallel to the plane of the substrate.

Each pad 142′ does not extend over the whole thickness of the insulating layer 141. It extends however over more than half of this thickness, and even more than 80% or even more than 90% of this thickness.

It is then possible to distinguish two sub-layers in the insulating layer 141:
a sub-layer receiving the pads 142′, in which the aforementioned advantages are found, as mentioned with reference to FIGS. 1A and 1B; and
a sub-layer not receiving the pads, but having a reduced thickness.

Preferably, the pads sink into the insulating layer from its upper face, on the side opposite to the substrate. The sub-layer not receiving the pads then extends on the side of the substrate.

According to other alternatives, not represented, the pads have non-circular sections in planes parallel to the plane of the substrate, for example square or rectangular sections, of side comprised for example between 10 μm and 40 μm.

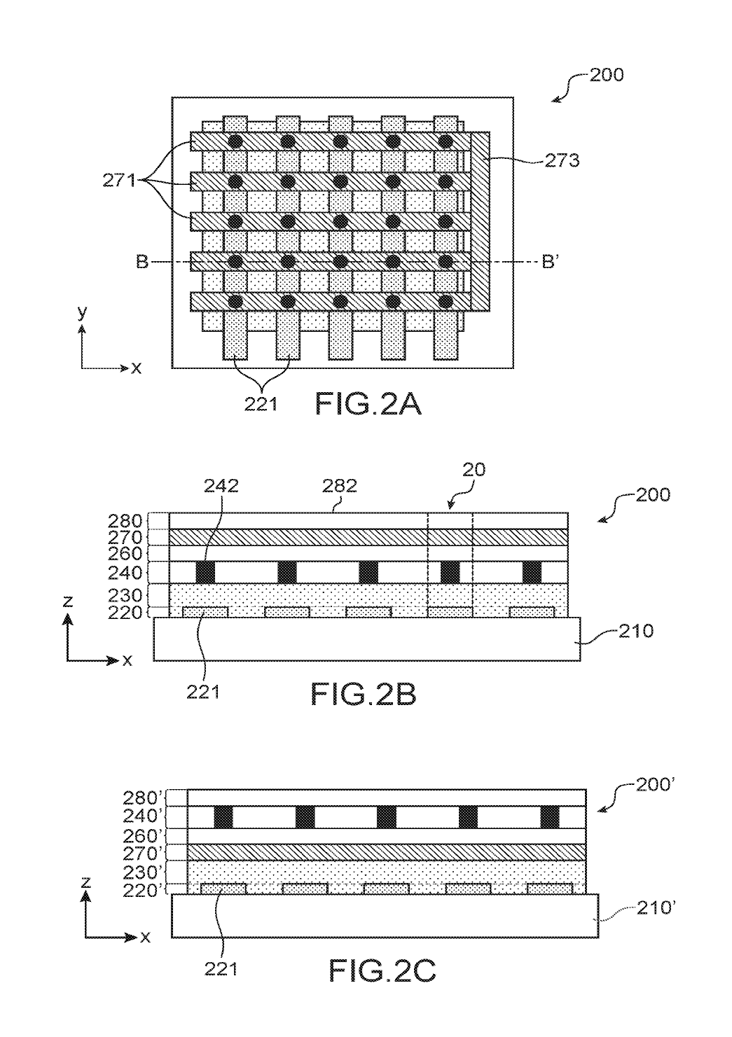

FIGS. 2A and 2B schematically illustrate a second embodiment of a heat pattern sensor 200 according to the invention. FIG. 2A is a schematic top view, in a plane parallel to the plane (xOy). FIG. 2B is a sectional view in a plane BB′ parallel to the plane (xOz).

In this second embodiment, each pixel comprises a heating element, and these heating elements are exploited to carry out a passive addressing of the pixels of the sensor.

The heating elements of a same line of pixels are electrically connected together to form a heating strip 271. Each heating strip 271 is configured to be able to be activated independently of the other heating strips. In other words, the heating elements of the pixels of a same line of pixels are able to heat the pyroelectric material portions of the pixels of said line, independently of the heating elements of the pixels of the other lines. The heating strips 271 each have a first end, suitable to being connected to a non-zero electrical potential, and a second end, preferably connected to the ground. Here, the second ends of all the heating strips are connected together through a conducting portion 273.

Moreover, the charge collection electrodes of a same column of pixels are electrically connected together to form a charge collection macro-electrode 221. Each charge collection macro-electrode 221 is formed by an electrically conducting strip, in contact with the pyroelectric material portions of the pixels of said column of pixels, and distinct from the electrically conducting strips forming the charge collection macro-electrodes of the other columns of pixels.

Each charge collection macro-electrode 221 makes it possible to measure the sum of the pyroelectric charges generated in a same column of pixels. If at each instant only a single one of the heating strips 271 is activated, in each column of pixels there is only a single pixel that generates pyroelectric charges. The pyroelectric charges collected by the charge collection macro-electrode 221 then relate to this single pixel. A passive addressing of the pixels of the sensor is thereby carried out.

Such a sensor is described in the French patent application n° 16 57391, mentioned in the introduction.

The terms “line” and “column” may be exchanged, which would correspond to a simple 90⁰ rotation of the sensor.

In the embodiment of FIGS. 2A and 2B, the heat pattern sensor 200 comprises, superimposed in this order, above the substrate 210:
a stage 220 of charge collection electrodes, receiving the charge collection macro-electrodes 221;
a stage 230 including a pyroelectric material, identical to that described with reference to FIGS. 1A and 1B;
an electromagnetic shielding stage 240, identical to that described with reference to FIGS. 1A and 1B, or to FIG. 1C;
an electrical insulation layer 260, such as described with reference to FIGS. 1A and 1B;
a so-called heating stage 270, receiving the heating strips 271; and
a protective layer 280, such as described with reference to FIGS. 1A and 1B.

The contact surface 281 of the sensor is here formed by an upper face of the protective layer 280, on the side opposite to the substrate 210.

The stage 220 of charge collection electrodes is similar to that which has been described with reference to FIGS. 1A and 1B, except that the charge collection electrodes of a same column of pixels are formed together in one piece. They are distributed, along the axis (Ox), according to a distribution pitch less than or equal to 150 μm, for example 90 μm, or 80 μm, or 50.8 μm.

The heating strips 271 of the heating stage 270 are distributed, along the axis (Oy), according to a distribution pitch which is preferably identical to the distribution pitch of the charge collection macro-electrodes 221. Whatever the case, the heating strips 271 are preferably distributed according to a pitch less than or equal to 150 μm, for example 90 μm, or 80 μm, or 50.8 μm. The heating strips 271 preferably include a metal, for example gold or silver.

Each pixel 20 of the matrix of pixel is delimited laterally by the intersection between a charge collection macro-electrode 221 and a heating strip 271. In other words, each pixel is delimited laterally, in planes parallel to the plane of the substrate, by the contours of the intersection between the orthogonal projection, in such a plane, of a charge collection macro-electrode 221, and the orthogonal projection, in this same plane, of a heating strip 271.

Each pixel 20 receives a single pad 242 of the electromagnetic shielding stage 240. This pad thus extends into the electromagnetic shielding stage 240, while traversing an intersection region situated in a plane parallel to the plane of the substrate, at the intersection between an orthogonal projection of a macro-electrode 221 and an orthogonal projection of a heating strip 271.

FIG. 2C illustrates an alternative, which only differs from the embodiment of FIGS. 2A and 2B in that the electromagnetic shielding stage extends above the heating stage.

In particular, the heat pattern sensor 200′ comprises, superimposed in this order above the substrate 210′:
the stage 220′ of charge collection electrodes;
the stage 230′ including a pyroelectric material;
the heating stage 270′;
the electrical insulation layer 260′;
the electromagnetic shielding stage 240′; and
the protective layer 280′, distinct from the electromagnetic shielding stage 240′.

According to this alternative, each heating line of the heating stage 270′ also forms a reference electrode, common to all the pixels of a line of pixels of the matrix of pixels. Said heating line is able to be connected to a potential source, itself suitable to make a non-zero current circulate in the heating line. This current must remain constant during the reading of the charges on the charge collection electrodes of the associated pixels. When the other side of the heating line is connected to the ground, said potential source advantageously alternates between two constant values: a zero value where the heating line does not heat up, and a non-zero value where the heating line provides heating by Joule effect.

In an alternative, the heating stage 270′ comprises pairs of two strips parallel with each other, one dedicated to the heating of a line of pixels, and the other forming a reference electrode common to the pixels of the same line of pixels.

According to alternatives, not represented, of the embodiment of FIGS. 2A and 2B and the embodiment of FIG. 2C, the charge collection electrodes of a same column of pixels are not connected together, and the addressing of the pixels is of active type and requires selection means in each pixel, such as transistors.

The invention is not limited to the examples described above, and numerous alternatives may be implemented without going beyond the scope of the invention.

In particular, the invention applies to any type of thermal sensor comprising a matrix of pyroelectric capacitances, with or without heating elements, with heating elements that are distinct or laid out in heating strips parallel with each other.

The invention applies more specifically to sensors in which the distance between the contact surface and the plane of the upper faces of the lower electrodes of the pyroelectric capacitances is less than or equal to the pixel pitch of the sensor.

The heat pattern sensor according to the invention may comprise heating elements which are not connected together in heating lines.

The invention is not limited either to an active type detection, and also covers sensors suitable for a passive type detection, without heating element to heat the pyroelectric material portions of the pixels of the sensor.

When the dimensions of the pixel so allow, each pixel of the matrix of pixels may comprise a plurality of pads of the electromagnetic shielding stage.

In all the embodiments, the electromagnetic shielding stage extends between the stage including a pyroelectric material and the protective layer. Even so, intercalary stages may be situated between the electromagnetic shielding stage and the stage including a pyroelectric material, respectively between the electromagnetic shielding stage and the protective layer. Whatever the case, the protective layer forms a layer distinct from the electromagnetic shielding stage.

The sensor may include at least one reading circuit, for measuring a quantity of charges collected by a charge collection electrode, and, if need be, at least one circuit for controlling the heating, for sending electrical signals making it possible to heat the pixels of the sensor through heating elements. It may further comprise an electronic processing circuit able to construct a global image of a thermal pattern, from measurements made at the level of each of the pixels of the sensor.

The thermal pattern being able to be imaged by the sensor may be a papillary print, or any other pattern associated with an object having a heat capacity and a specific heat capacity.

The electromagnetic shielding stage may be produced by forming a matrix of pads, on which is deposited the insulating layer such that the material of the insulating layer is inserted between the pads.

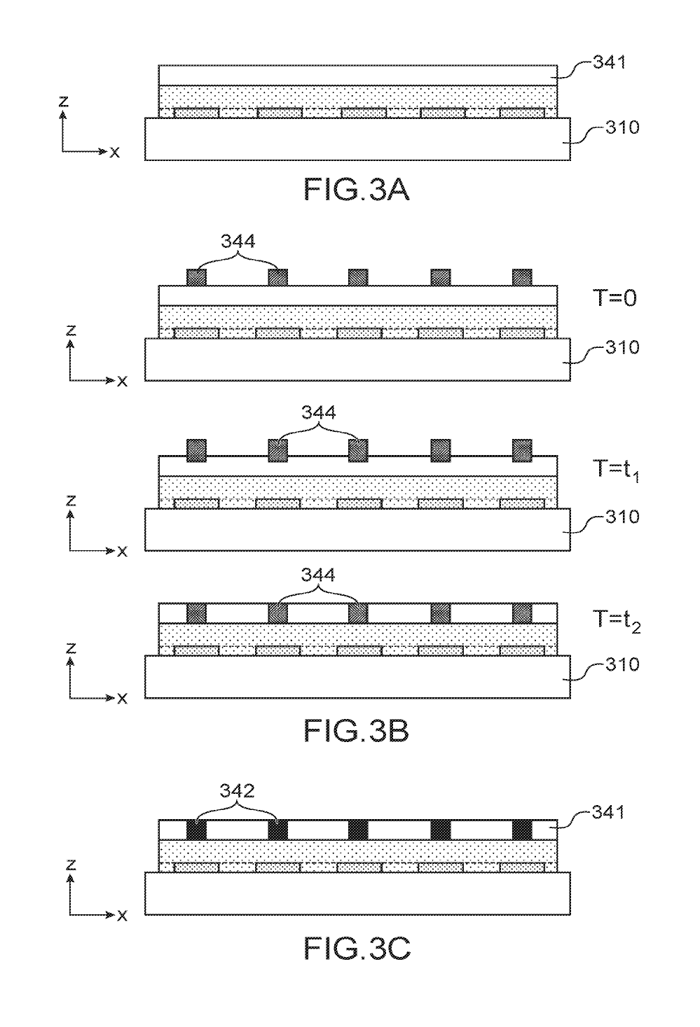

Hereafter is described, with reference to FIGS. 3A to 3C, a method according to the invention, more astute, for manufacturing the electromagnetic shielding stage of a heat pattern sensor according to the invention. This method comprises the following steps:

Step 1:

Depositing the insulating layer 341, such that it extends in one piece and without opening above the substrate 310 (FIG. 3A).

Here, but in a non-limiting manner, the insulating layer 341 is deposited on the stage including a pyroelectric material.

Step 2:

Depositing, on the insulating layer 341, an ink comprising, in suspension in a solvent, particles of a material with a thermal conductivity greater than that of the insulating layer. They are in particular metal or graphene particles.

The ink is deposited only at the desired places, along the axes (Ox) and (Oy), of the future pads of the electromagnetic shielding stage, the axes (Ox) and (Oy) defining the plane of the substrate.

The deposition of an ink is carried out for example by screen printing, or by ink jet printing, by rotogravure, by flexogravure, by offset gravure, etc.

The solvent is able to dissolve the insulating layer 341, such that the ink, at the spot where it has been deposited, locally dissolves the insulating layer and sinks into it.

In FIG. 3B, this step is illustrated at the instant T=0 of deposition of the ink, and at later instants T=t₁>0, and T=t₂>t₁. FIG. 3B shows pads 344, constituted of an ink, progressively sinking into the insulating layer 341, along the axis (Oz) orthogonal to the plane of the substrate 310.

For example, the insulating layer 341 includes PEDOT, and the ink includes particles of silver or graphene, in suspension in a solvent such as water, or cyclopentanone, or dimethysulfone (C₂H₆O₂S). Preferably, the ink comprises between 35% and 55% by volume of solvent, more preferentially between 40% and 50%.

Preferably, the ink locally dissolves the insulating layer 341 over its whole thickness, until reaching the layer, or the stage, situated under the insulating layer 341.

Step 3:

In a third step, illustrated in FIG. 3C, the ink is dried, for example by heating in an oven, to evacuate the solvent. There then only remains the metal or graphene particles, which form in the insulating layer 341 the pads 342 such as described above.

Such a method is advantageously implemented with an insulating layer 341 of reduced thickness, preferably of thickness less than or equal to 1.5 μm, and even less than or equal to 1.0 μm, and even less than or equal to 700 nm.

1: A heat pattern sensor comprising a matrix of pixels, each pixel comprising at least one pyroelectric capacitance which is formed by a pyroelectric material portion arranged between a so-called charge collection electrode and a so-called reference electrode, and the matrix of pixels comprising, superimposed above a substrate:
a stage of charge collection electrodes, comprising the charge collection electrodes of each of the pixels;
a stage including a pyroelectric material, comprising the pyroelectric material portions of each of the pixels; and
a protective layer, forming an outer layer of the matrix of pixels; the matrix of pixels further comprising a so-called electromagnetic shielding stage, electrically conducting, situated between the stage including a pyroelectric material and the protective layer;
wherein the electromagnetic shielding stage is constituted by a layer, called insulating layer, and by a plurality of pads distributed in the insulating layer, wherein the pads have a thermal conductivity greater than that of the insulating layer, and wherein each pad extends over more than half the thickness of the insulating layer and has a diameter less than a pixel pitch of the matrix of pixels.

2: The heat pattern sensor according to claim 1, wherein each pixel of the matrix of pixels comprises a portion of the electromagnetic shielding stage, said portion receiving a single pad.

3: The heat pattern sensor according to claim 1, wherein the pads of the electromagnetic shielding stage have a thermal conductivity at least ten times greater than that of the insulating layer.

4: The heat pattern sensor according to claim 1, wherein the pads include metal or graphene, and the insulating layer includes at least one electrically conducting polymer.

5: The heat pattern sensor according to claim 4, wherein the pads include silver, and the insulating layer includes a mixture of poly(3,4-ethylenedioxythiophene) and sodium poly(styrene sulfonate), designated PEDOT: PSS.

6: The heat pattern sensor according to claim 1, wherein the pads each sink in over more than half the thickness of the insulating layer.

7: The heat pattern sensor according to claim 6, wherein the pads each sink in over the whole thickness of the insulating layer.

8: The heat pattern sensor according to claim 1, wherein the pads each have a diameter comprised between 10 μm and 120 μm, the diameter of a pad being the greatest length measured along a rectilinear axis, on this pad, in a plane parallel to an upper or lower face of the substrate.

9: The heat pattern sensor according to claim 1, wherein:
each pixel further comprises a heating element, able to heat by Joule effect the pyroelectric material portion of said pixel; and
a heating stage, comprising the heating elements of each of the pixels, extends into the matrix of pixels between the stage including a pyroelectric material and the protective layer.

10: The heat pattern sensor according to claim 9, wherein:
the heating elements of a same line of pixels are formed together in one piece, in a same heating strip;
the charge collection electrodes of a same column of pixels are formed together in one piece, in a same charge collection macro-electrode; and
each pad of the electromagnetic shielding stage extends through an intersection region between a projection of a heating strip and a projection of a charge collection macro-electrode, said projections being orthogonal projections in a plane parallel to an upper or lower face of the substrate.

11: The heat pattern sensor according to claim 9, wherein the matrix of pixels comprises, superimposed:
the stage of charge collection electrodes;
the stage including a pyroelectric material;
the electromagnetic shielding stage, further forming the reference electrodes of the pixels of the matrix of pixels;
an electrical insulation layer;
the heating stage; and
the protective layer.

12: The heat pattern sensor according to claim 9, wherein the matrix of pixels comprises, superimposed:
the stage of charge collection electrodes;
the stage including a pyroelectric material;
the heating stage the heating elements further forming the reference electrodes of the pixels of the matrix of pixels;
an electrical insulation layer;
the electromagnetic shielding stage; and
the protective layer.

13: A method for manufacturing the matrix of pixels of a heat pattern sensor according to claim 1, wherein a step of producing the electromagnetic shielding stage includes the following steps:
depositing the insulating layer, such that it extends without opening above the substrate;
depositing, on said insulating layer, an ink including particles in suspension in a solvent, the solvent being able to dissolve locally the insulating layer; and
evacuating the solvent, to form the pads of the electromagnetic shielding stage, distributed in the insulating layer.
